(19) United States
(12) Patent Application Publication
(10) Pub. No.: US 2026/0093857 A1
(43) Pub. Date: Apr. 2, 2026

(54) LLM-GENERATED INFRASTRUCTURE DESIGN

(71) Applicant: ORACLE INTERNATIONAL CORPORATION, Redwood Shores, CA (US)

(72) Inventors: Paul Gregory GREENSTEIN, Hopkinton, MA (US); Zbigniew HOLKA, Solihull (GB)

(21) Appl. No.: 18/901,714

(22) Filed: Sep. 30, 2024

(51) Int. Cl. G06F 30/13

(52) U.S. Cl. CPC G06F 30/13

(57) ABSTRACT

Systems, methods, and other embodiments associated with LLM-based generation of computing infrastructure are described. In one embodiment, an example method includes accessing infrastructure requirements for compute infrastructure that are in human language. The example method includes translating the infrastructure requirements into a physical infrastructure topology using one or more large language models. The example method includes converting the physical infrastructure topology into an executable deployment specification. And, the example method includes executing the deployment specification to automatically configure a target computer system to have the compute infrastructure described by the infrastructure requirements.

### BACKGROUND

Cloud platforms have become popular tools for hosting software applications due to their adaptability, scalability, and accessibility. While the computing environment of a cloud platform is largely virtualized, clients of the cloud platform are tasked with the planning and configuration of physical infrastructure that executes the client's software applications. The processes for design and deployment of physical infrastructure are inconsistent and resistant to automation due to the open-ended nature of the design process.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments one element may be implemented as multiple elements or that multiple elements may be implemented as one element. In some embodiments, an element shown as an internal component of another element may be implemented as an external component and vice versa. Furthermore, elements may not be drawn to scale.

FIG. 1 illustrates one embodiment of an infrastructure production system that is associated with LLM-based generation and deployment of designs for computing infrastructure.

FIG. 2 illustrates one embodiment of an infrastructure production method that is associated with LLM-based generation and deployment of designs for computing infrastructure.

FIG. 3 illustrates one embodiment of a method for translating the infrastructure requirements into a PIT in two stages, which is associated with LLM-based generation and deployment of designs for computing infrastructure.

FIG. 4 illustrates an example infrastructure design process that is associated with LLM-based generation and deployment of designs for computing infrastructure.

FIG. 5 illustrates an example LIT graph that is associated with LLM-based generation and deployment of designs for computing infrastructure.

FIG. 6 illustrates an example PIT graph that is associated with LLM-based generation of designs for computing infrastructure.

FIG. 7 illustrates an embodiment of a computing system configured with the example systems and/or methods disclosed.

### DETAILED DESCRIPTION

Systems, methods, and other embodiments are described herein that provide for large language model (LLM)-based generation and deployment of designs for computing infrastructure. In one embodiment, an infrastructure production system uses one or more LLMs to generate infrastructure designs, and then automatically deploys the generated designs. For example, the infrastructure production system automatically generates a deployment specification in executable infrastructure code from natural-language infrastructure requirements documentation. In one embodiment, the infrastructure production system automatically generates logical and physical infrastructure topologies as intermediate steps between the documentation and the deployment specification for improved accuracy. In one embodiment, the infrastructure production system automatically executes the generated deployment specification to automatically provision the infrastructure in a target environment, such as a cloud computing system.

In one embodiment, the infrastructure production system improves over existing processes for infrastructure design and deployment by enabling rapid or even near real time deployment of compute infrastructure, allowing organizations to scale existing configurations of physical infrastructure quickly to meet demand or more rapidly recover from a failure—or even to develop and deploy new physical infrastructure configurations—based only on a set of infrastructure requirements for the physical infrastructure. In one embodiment, the infrastructure production system improves over existing processes by enhancing accuracy, consistency, and predictability of physical infrastructure designs due to employment of LLMs to design the infrastructure topologies. And, in one embodiment, the infrastructure production system improves over existing processes by being agnostic to the target cloud platform. For example, the infrastructure production system produces intermediate logical infrastructure designs that are tailored to support a specific application, and then uses them to generate one or more divergent physical infrastructure designs that share a logical arrangement for deployment to the differing hardware native to various cloud platforms. Thus, in one embodiment, the infrastructure production system automatically develops infrastructure to support an application that it can then automatically configure on a wide variety of cloud platforms.

### Definitions

As used herein, “Logical Infrastructure Topology” (LIT) refers to a graph (or collection of textual tokens translatable to a graph) that represents an architecture of system, focusing on the relationships and interactions between different functional elements or components without specifying the actual physical devices or resources involved. In a LIT, the emphasis is on how various components of the system are functionally organized and interconnected, such as the flow of data, communication paths, and the arrangement of software or service components. A LIT serves as a blueprint that outlines logical structure and behavior of the system, independent of the underlying physical infrastructure that will implement it.

As used herein, “Physical Infrastructure Topology” (PIT) refers to a graph (or collection of textual tokens translatable to a graph) that represents the concrete, real-world implementation of a system's architecture, specifying the actual physical devices, resources, and connections that support the logical components described in the LIT. In a PIT the emphasis is on detailing the specific hardware, network configurations, storage solutions, and other physical elements that will be used to realize the system. For example, this may include specifying devices like servers, routers, switches, IP address ranges, and the physical connections between them.

Note, a PIT serves as a mapping of the LIT onto actual infrastructure that will be deployed and managed in a data center or cloud environment. The process of creating the PIT accounts for the characteristics of the infrastructure other than function, such as operational characteristics. Thus, while LIT creation may disregard specifications about performance, response time, availability, etc. in the infrastructure requirements, creation of a PIT from the LIT takes note of these operational characteristics in the infrastructure requirements and generates a PIT that satisfies them along with the functional characteristics of the LIT.

As used herein, “infrastructure requirements” include (i) functional requirements that specify the tasks to be performed by a compute infrastructure and (ii) non-functional (i.e., operational) requirements that specify criteria for the operation of the compute infrastructure. The infrastructure requirements may be expressed in human language in a requirements document. For example, the infrastructure requirements may describe compute infrastructure with human language to a level of detail sufficient to enable design of the compute infrastructure.

As used herein, “human language” refers to natural, everyday language used by people to communicate, including written text or spoken dictation that is used to express infrastructure requirements for compute infrastructure. Human language includes, but is not limited to, written and typewritten forms of text that are converted into electronic data, spoken dictation that is received by a computing device and converted into electronic data, and text extracted from spoken dictation using voice-to-text conversion and/or speech recognition technology. An item of electronic data (such as a changed design requirement) is “in human language” where the electronic data expresses, records, defines, stores, or otherwise represents textual (written) or vocal (spoken) human language.

As used herein, the terms “computing infrastructure” and “compute infrastructure” (occasionally referred to herein simply as “infrastructure” for short) refers to a collection of hardware, software, networks, facilities, and related services that deliver information technology operations.

No action or function described or claimed herein is performed by the human mind. An interpretation that any action or function can be performed in the human mind is inconsistent with and contrary to this disclosure.

### —Example Infrastructure Production System—

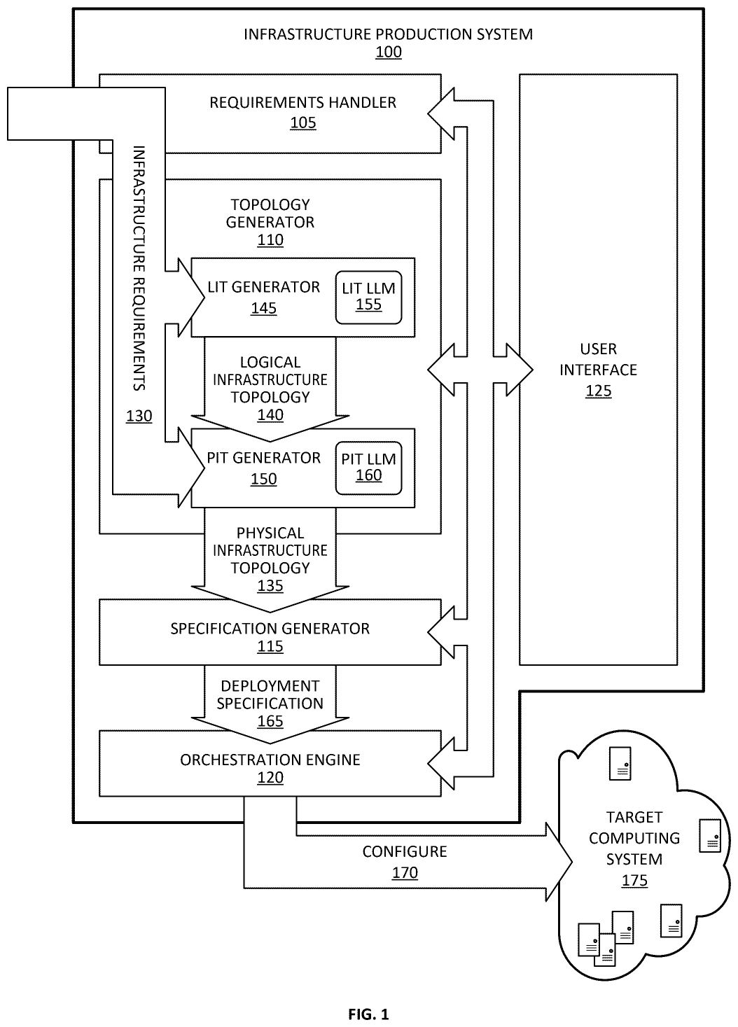

FIG. 1 illustrates one embodiment of an infrastructure production system 100 that is associated with LLM-based generation and deployment of designs for computing infrastructure. Infrastructure production system 100 includes components configured to implement an LLM-based process for automatically deploying compute infrastructure in a computing system (such as a cloud computing system) based on input of human-language infrastructure requirements for the compute infrastructure. In one embodiment, infrastructure production system 100 includes a requirements handler 105, a topology generator 110, a specification generator 115, and an orchestration engine 120. In one embodiment, infrastructure production system 100 may further include a user interface 125. In one embodiment, the components of infrastructure production system 100 are discrete hardware components or software modules. In one embodiment, the components of infrastructure production system 100 intercommunicate to provide data to one another, for example by electronic messages as discussed below under the heading “Cloud or Enterprise Embodiments”.

In one embodiment, requirements handler 105 is configured to access infrastructure requirements 130 for compute infrastructure. The infrastructure requirements 130 are in human language. For example, the infrastructure requirements 130 are written as textual descriptions or outlines of features of a compute infrastructure. The infrastructure requirements may detail what the compute infrastructure is to accomplish. For example, the infrastructure requirements include functional requirements: requirements that describe what functions, behaviors, actions, or tasks the compute infrastructure is to perform. Functional requirements are consumed at a LIT generation stage by LIT generator 145. And, for example, the infrastructure requirements include non-functional requirements, which may include performance criteria (such as response time, sustained volume of transactions, pace, etc.), operational constraints (e.g., availability, reliability, disaster recovery), technological constraints (e.g., standards compliance, desired technologies or products), and quality attributes (e.g., maximum tolerable defect rate and maintainability). Non-functional requirements may be disregarded at a LIT generation stage, and are consumed at a PIT generation stage by PIT generator 150.

In one embodiment, topology generator 110 is configured to translate the infrastructure requirements 130 into a PIT 135 using LLM(s). In one embodiment, translation of the infrastructure requirements 130 into the PIT 135 further comprises translating the infrastructure requirements 130 into an intermediate LIT 140 prior to producing the PIT 135. In one embodiment, therefore, topology generator 110 includes a LIT generator 145 and a PIT generator 150.

In one embodiment, LIT generator 145 is configured to translate the infrastructure requirements 130 into the LIT 140 using a first LLM 155. First LLM 155 is trained to generate logical infrastructure topologies. In one embodiment, LIT generator 145 is configured to generate the LIT 140 as a collection of tokens in a graph representation language.

In one embodiment, PIT generator 150 is configured to translate the infrastructure requirements 130 and the LIT 140 into the PIT 135 using a second LLM 160. Second LLM 160 is trained to generate physical infrastructure topologies based on infrastructure requirements that are in human language form or format and a LIT that is expressed in the graph representation language. In one embodiment, PIT generator 150 is configured to generate the PIT 135 as a collection of tokens in the graph representation language.

In one embodiment, specification generator 115 is configured to convert the PIT 135 into an executable deployment specification 165. In one embodiment, the conversion of the PIT 135 produces the executable deployment specification 165 in a pre-selected configuration language. For example, the executable deployment specification 165 may be written in YAML code, such as in one or more Ansible playbooks. Or, for example, the executable deployment specification 165 may be written in Terraform code, such as a configuration file(s) written in HashiCorp Configuration Language (HCL).

In one embodiment, orchestration engine 120 is configured to execute the deployment specification 165 to automatically configure 170 a target computing system 175 as specified by the infrastructure requirements 130. In one embodiment, orchestration engine 120 is an instance of the automation engine Ansible—an automation framework and configuration management tool configured to provision compute infrastructure in accordance with tasks described in playbooks. In one embodiment, orchestration engine 120 is an instance of the core engine of Terraform—an infrastructure as code (IaC) tool configured to provision compute infrastructure as described in a declarative way in configuration files. Thus, in one embodiment, orchestration engine 120 is configured to orchestrate a deployment process so as to implement individual parts of the deployment specification in a correct order.

In one embodiment, target computing system 175 is physical compute infrastructure (i.e., a hardware environment) that is configurable into various PITs by orchestration engine 120. For example, target computing system 175 is a cloud computing system, such as (i) a public cloud operated by a third-party cloud service provider other than an enterprise that is the cloud client, or (ii) a private cloud operated on premises of the enterprise client, or (iii) a hybrid cloud possessing resources both on premises of the enterprise client and in the environment of one or more cloud service providers, in any combination. In one embodiment, target computing system 175 is a virtualized on-premises data center. (Note, in one embodiment, the algorithms described herein for LIT and PIT generation are also applicable to non-virtualized environments. In a non-virtualized environment, the infrastructure production method 200 below can proceed through block 220 to produce a build-out workflow or other deployment specification. The subsequent automated configuration described in block 225 relies on virtualization.)

Target computing system 175 includes computing hardware components that inter-operate to provide computing resources. For example, target computing system 175 includes one or more bare metal computer servers (which include physical processors, memory, and non-transitory computer-readable storage media) interconnected by a physical data network. Target computing system 175 is configured to host physical compute infrastructure, including virtual machines, networks and subnetworks, databases and other storage, load balancers, bastions, gateways, firewalls or other infrastructure components. Such compute infrastructure components may be provisioned atop the underlying bare metal hardware of target computing system 175.

In one embodiment, user interface 125 is configured to present outputs of the infrastructure production system 100 and accept inputs from a user of the infrastructure production system 100. In one embodiment, the user interface is a graphical user interface. In one embodiment, the user interface 125 is configured to present the LIT 140 as a LIT graph for a first user approval before proceeding to translate the LIT 140 into the PIT 135. And the user interface 125 is configured to present the PIT as a PIT graph for a second user approval before proceeding to convert the PIT into the executable deployment specification.

In one embodiment, presentation of a topology as a graph in the user interface 125 includes parsing graph representation language of the topology to identify entities and relationships between the entities in the topology. And, once the entities and relationships are detected, presentation further displays the entities (such as servers, bastions, load balancers, compute instances, and databases) as nodes, interconnected by edges representing the relationships between the entities. For example, the graph of entities and relationships may be shown on a display of a computer terminal.

In one embodiment, user interface 125 is configured to solicit user inputs, such as approvals or corrections regarding the LIT 140 and PIT 135 displayed as graphs. In one embodiment, the user interface 125 includes user interface elements configured to accept user inputs.

In one embodiment, the user interface 125 may include text boxes, selection controls (such as dropdown menus, radio buttons, checkboxes, and toggle switches). For example, the user interface 125 may be configured to accept corrections, adjustments, or other changes to aspects of entities and relationships through user interface elements that are associated with the entities and relationships. Or, for example, the user interface 125 may be configured to accept an identification or specification of a target system to be configured in accordance with the infrastructure requirements 130 through user interface elements. The user interface 125 may also include buttons, such as a button to approve a topology with no changes, a button to submit changes to the topology, or other action buttons. The user interface 125 may also include file upload controls that allow the user to specify a file that includes the infrastructure requirements 130. In one embodiment, the user interface 125 is configured to enable the user to remove or add entities and relationships, and further to enable the user to rearrange the relationships between entities.

In one embodiment, the user interface may be a graphical user interface (GUI) that is duplex (i.e., supports two-way communication between the user and infrastructure production system 100 in real time). The GUI may be configured to display an infrastructure graph (LIT graph or PIT graph) graphically. The GUI may be configured to allow a user to interactively modify the infrastructure graph, for example by drag-and-drop of visual elements (such as nodes and edges of the infrastructure graph).

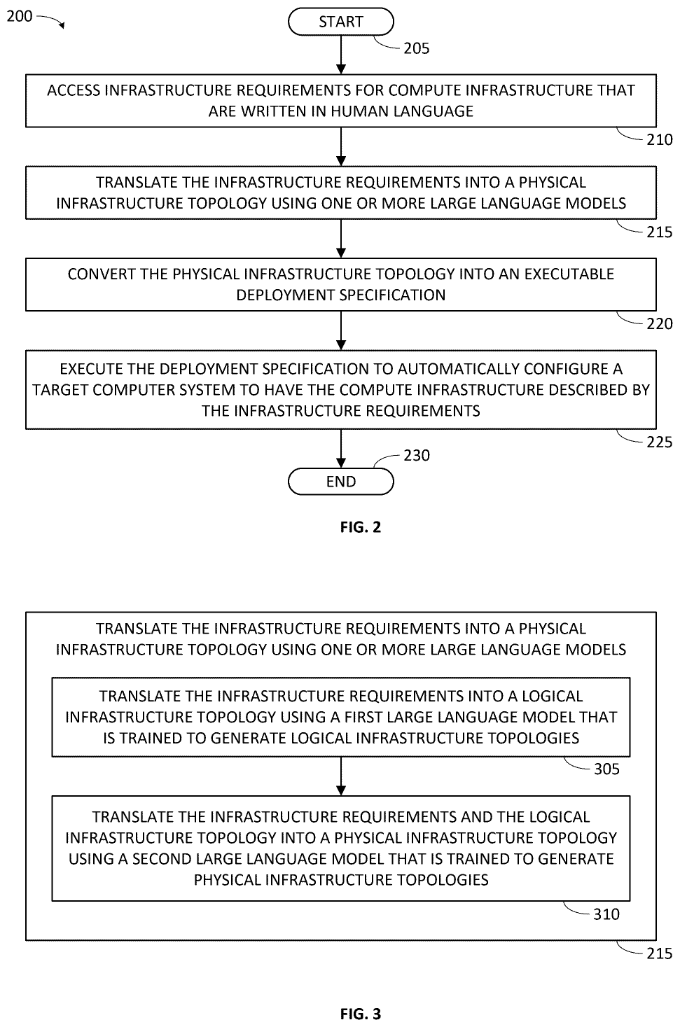

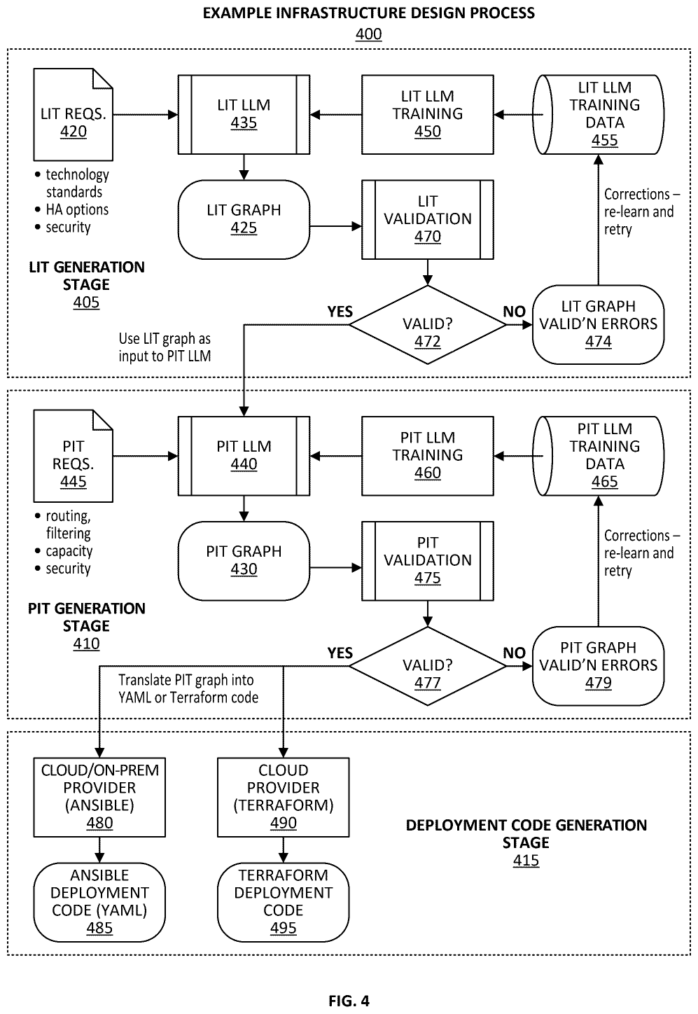

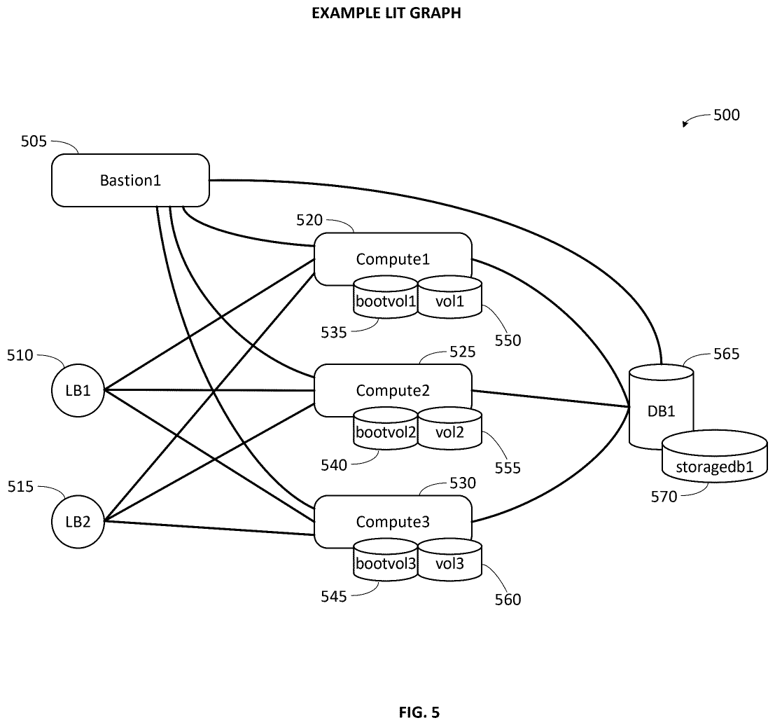

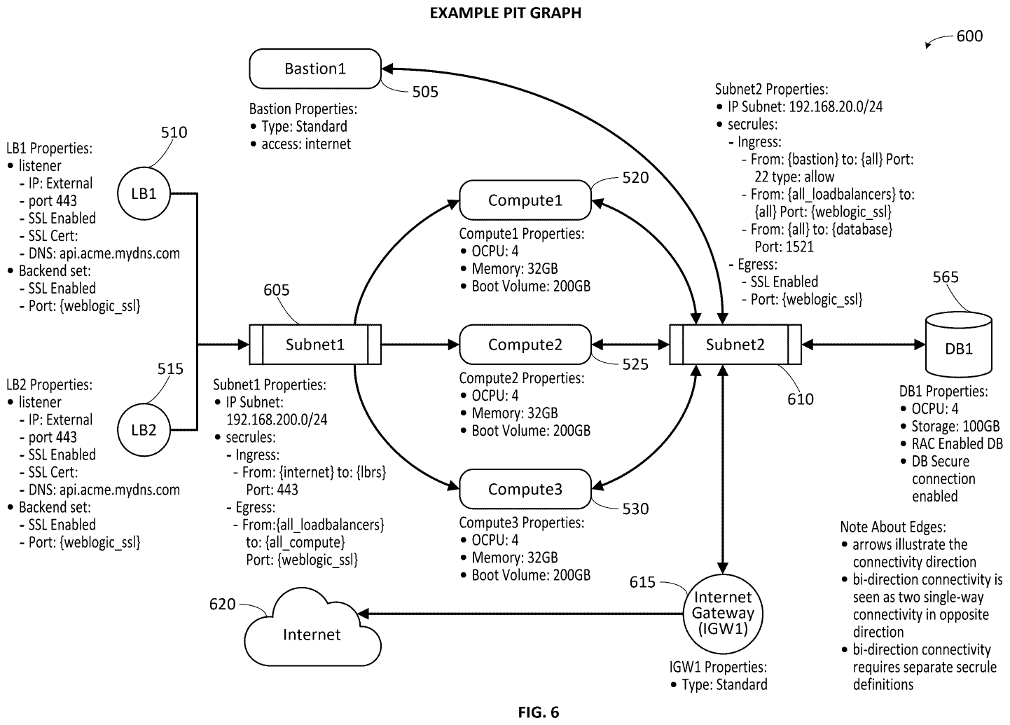

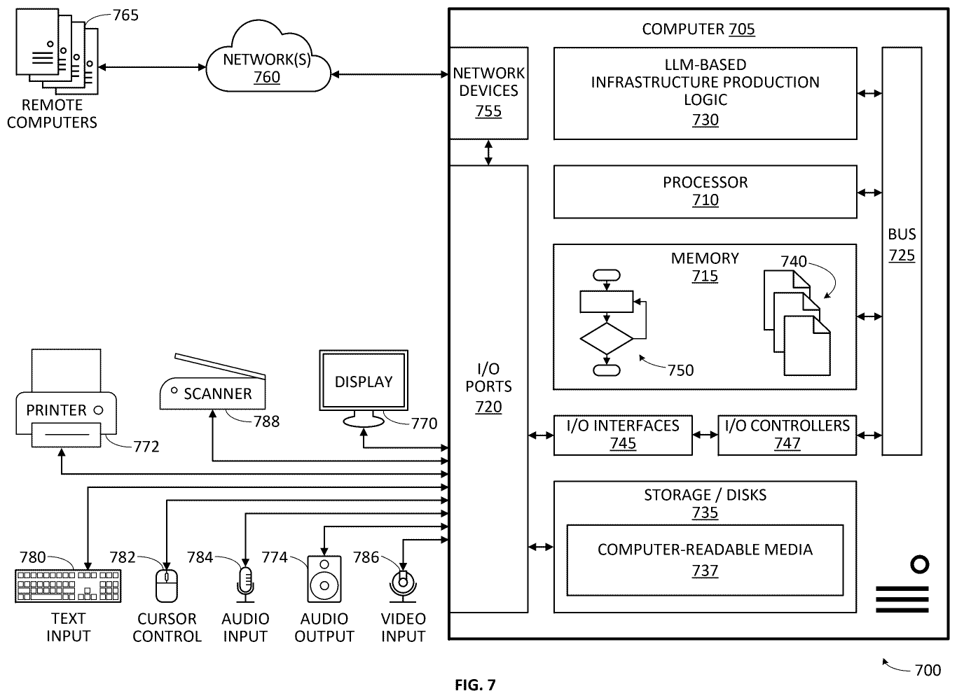

Further details regarding infrastructure production system 100 are presented herein. In one embodiment, operations of infrastructure production system 100 will be described with reference to infrastructure production method 200 of FIGS. 2 and 3. And, in one embodiment, operations of infrastructure production system 100 will be described with reference to example infrastructure design process 400 of FIG. 4. In one embodiment, examples of a LIT graph 500 and a PIT graph 600 that may be generated by the infrastructure production system 100 from infrastructure requirements will be described with reference to FIGS. 5 and 6, respectively.

### —Example Infrastructure Production Method—

FIG. 2 illustrates one embodiment of an infrastructure production method 200 that is associated with LLM-based generation and deployment of designs for computing infrastructure. Infrastructure production method 200 is one method for automatically generating and implementing a deployment specification for computing infrastructure from infrastructure requirements that are in human language form or format.

In one embodiment, as a general overview, infrastructure production method 200 (i) accesses infrastructure requirements for compute infrastructure that are in human language form or format; (ii) translates the infrastructure requirements into a PIT using LLMs, for example generating a LIT from the infrastructure requirements using a first LLM trained for such generation, and then generating the PIT from the infrastructure requirements as well as the LIT using a second LLM trained for such generation; (iii) converts the PIT into an executable deployment specification; and (iv) executing the deployment specification to automatically configure a target computer system as specified in the infrastructure requirements.

Put another way, as an example, infrastructure production method 200 (i) retrieves a chosen infrastructure requirements file that outlines a planned compute infrastructure; (ii) generates an architecture for the physical infrastructure from the infrastructure requirements using LLMs (or other generative artificial intelligence (AI) models), for example that initially producing a layout for the logical infrastructure that is then used to inform the arrangement of the physical infrastructure; (iii) maps the generated architecture for the physical infrastructure into infrastructure code; and then (iv) executes the infrastructure code to produce, in a target compute environment, the compute infrastructure outlined in the infrastructure requirements.

In one embodiment infrastructure production method 200 initiates at START block 205 in response to infrastructure production system 100 determining one or more of (1) that infrastructure production system 100 has received an instruction to configure a target computer system as described by provided infrastructure requirements; (2) that infrastructure production system 100 has received an instruction to generate an executable deployment specification from provided infrastructure requirements; (3) infrastructure production system 100 has received a set of infrastructure requirements for computing infrastructure that are in human language form or format; (4) that an instruction to perform infrastructure production method 200 has been received; (5) a user or administrator has initiated infrastructure production method 200; (6) it is currently a time at which infrastructure production method 200 is scheduled to be run; or (7) infrastructure production method 200 should commence in response to satisfaction of some other condition. As used herein, the use of the term “in response to” an event indicates that an action or task is automatically initiated, carried out, completed, or otherwise performed automatically upon the occurrence of the event.

In one embodiment, a computing system configured by computer-executable instructions to execute functions of infrastructure production system 100 executes infrastructure production method 200. In one embodiment, at START block 205, infrastructure production system 100 (1) provisions (i.e., allocates and initializes) resources of the computing system that are used by infrastructure production system 100, such as processor, memory and storage (for example, for holding outputs of the generated infrastructure topologies and executable deployment specifications), (2) establishes access to one or more networks for the resources, such as access to (a) internal networks for communication among components of the infrastructure production system 100 and (b) external networks for communication with other computing systems (for example, the target computing system); (3) connects to data sources (such as databases, data stores, file systems, and cloud storage) used by the infrastructure production method 200, such as data sources that hold the input infrastructure requirements and trained LLMs; and (4) configures the computing system with system settings, software dependencies and libraries, and modules for the components of infrastructure production system 100. Following initiation at START block 205, infrastructure production method 200 proceeds to block 210.

At block 210, infrastructure production method 200 accesses infrastructure requirements for compute infrastructure that are in human language. In one embodiment, infrastructure production method 200 is provided with a pre-specified set of infrastructure requirements. The infrastructure requirements may be provided in a file located at a provided file path, as a specified record in a database, or received by input through a user interface. In one embodiment, infrastructure production method retrieves the infrastructure requirements from their location in storage, and formats them for use by downstream processes. In short, the infrastructure production method 200 reads, retrieves, or otherwise gets a compute infrastructure design. The infrastructure requirements are in human language, and may therefore be informal, and not necessarily follow a particular structure.

In one embodiment, where the infrastructure requirements are provided as a file, the infrastructure production method 200 reads a path to the file, locates the file, opens the file, reads the contents of the file, extracts the infrastructure requirements from the text within the file, and stores the extracted infrastructure requirements for subsequent analysis. In one embodiment, where the infrastructure requirements are stored in a database, the infrastructure production method 200 reads a query configured to retrieve the infrastructure requirements from the database, connects to the database, executes the query, processes the results of the query to obtain the infrastructure requirements, and stores the obtained infrastructure requirements for subsequent analysis. In one embodiment, where the infrastructure requirements are obtained by user input through a user interface, the infrastructure production method 200 prompts the user in the interface to enter the infrastructure requirements, waits for user entry of data that includes the infrastructure requirements, captures the data as it is entered into the user interface, processes the entered data to extract the infrastructure requirements, and stores the extracted infrastructure requirements for subsequent analysis.

In one embodiment, the steps of block 210 are performed by requirements handler 105. At the conclusion of block 210, infrastructure production method 200 has obtained infrastructure requirements that are in human language form or format for subsequent analysis in infrastructure production method 200. Processing continues to block 215.

At block 215, infrastructure production method 200 translates the infrastructure requirements into a PIT using one or more LLMs. For example, LLM(s) are used to interpret the infrastructure requirements and derive a PIT from the requirements for the computing infrastructure. The LLM(s) may produce the PIT as text, such as code in a graph representation language. Thus, in one embodiment, the LLM(s) convert the criteria for the compute infrastructure that are described in the infrastructure requirements into PIT graph that defines an architecture for the compute infrastructure.

In one embodiment, the infrastructure production method 200 accesses the infrastructure requirements, and dynamically generates one or more prompts based on the infrastructure requirements. The dynamically generated prompts are configured to cause the one or more LLMs to produce the PIT. The infrastructure production method 200 passes the dynamically generated prompts to the one or more LLMs. The responses to the prompts include the PIT. Infrastructure production method 200 captures and stores the physical infrastructure.

Referring briefly to FIG. 3, FIG. 3 illustrates one embodiment of an LLM-based method for translating the infrastructure requirements into a PIT in a two-stage or two-phase process. The two-stage process is one example way to perform functions of block 215. The two-stage process translates the infrastructure requirements into an intermediate LIT prior to producing the PIT. In one embodiment, the two-stage process employs two discrete LLMs that are specially fine-tuned for, respectively, generation of logical infrastructure topologies from infrastructure requirements, and generation of physical infrastructure topologies from both infrastructure requirements and a LIT.

At a first stage 305, the infrastructure production method 200 translates the infrastructure requirements into a LIT (LIT) using a first LLM that is trained to generate logical infrastructure topologies. In one embodiment, infrastructure production method loads (or otherwise accesses) the first LLM, dynamically generates a prompt for generation of the LIT from the infrastructure requirements, submits the prompt to the first LLM, and then captures the response from the first LLM.

In one embodiment, the infrastructure graph includes nodes and edges. The nodes represent infrastructure entities. As a non-exhaustive list of examples, the nodes may represent virtual machines (such as compute units or bastions), Kubernetes nodes, load balancers, and storage devices (such as boot volumes, storage volumes, and databases). The edges represent connections between the infrastructure entities, such as a network path or a storage device connection. In one embodiment, the graph representation language may express these edges and nodes as sequences of tokens (for example as described with reference to Tables 2 and 3 below), rendering the infrastructure graphs amenable to generation by a LLM.

In one embodiment, the prompt for generation of the LIT is dynamically generated by loading and populating a template prompt for LIT generation. The template prompt for LIT generation includes (i) infrastructure requirements and (ii) graph representation language as populatable fields. The template prompt for LIT generation includes instructions to generate a LIT graph in the graph representation language from the infrastructure requirements. For example, the template prompt for LIT generation may be something like “Generate a logical infrastructure topology graph in [GraphRepresentationLanguage] for the following infrastructure requirements: [InfrastructureRequirements].”

The template prompt includes populatable fields: [GraphRepresentationLanguage] for specifying a graph representation language for the LIT graph; and [InfrastructureRequirements] for providing the infrastructure requirements to be satisfied by the LIT graph. In one embodiment, the [InfrastructureRequirements] inserted into the template prompt is the text of infrastructure requirements provided as input to the infrastructure production system (such as infrastructure requirements 130). In one embodiment, before inclusion in the template prompt, the text of the infrastructure requirements is filtered to retain the functional requirements (which are used to generate a LIT) and remove the non-functional requirements (which are disregarded when generating a LIT). In one embodiment, the template prompt may state that the LIT graph should be generated “for the functional requirements described in the following infrastructure requirements: [InfrastructureRequirements].”

Infrastructure production method 200 submits the populated prompt for generation of the LIT to the first LLM, for example by making an API call to an API endpoint of the first LLM. The first LLM tokenizes and embeds the prompt for generation of the LIT, including the infrastructure requirements and selected graph representation language. The first LLM applies attention mechanisms to focus on relevant parts of the infrastructure requirements that inform the design of the LIT. For example, the first LLM is trained to focus on understanding the functional components and their interactions as laid out in the infrastructure requirements. The first LLM applies its trained understanding of logical infrastructure design principles to synthesize the relevant parts of the infrastructure requirements into a text description of the LIT. For example, the first LLM generates a series of graph representation language tokens that describe a graph of the LIT.

Infrastructure production method 200 captures and stores the graph representation language expression of the LIT (for short, the “LIT graph text”) produced by the first LLM. The LIT graph text is thus expressed as a text data structure. For example, infrastructure production method 200 reads the LIT graph text from an API endpoint of the first LLM, and writes the LIT graph text to a file, database, memory, or other storage to make the LIT graph text available for subsequent use. As a practical matter, the graph representation language entities in the LIT will then be further enhanced with additional properties pertinent to infrastructure entities and their associations in a second stage 310, which generates a PIT based on the LIT.

In one embodiment, the first LLM is trained to generate logical infrastructure topologies using a first training dataset that includes corresponding pairs of historical (previously created) infrastructure requirements and historical LIT graphs that are considered to satisfy the historical infrastructure requirements. In one embodiment, the corresponding pairs of historical infrastructure requirement and historical LIT graph may be obtained from a database of previously implemented deployments of compute infrastructure.

In one embodiment, to train the first LLM to generate logical infrastructure topologies based on infrastructure requirements, the infrastructure production method 200 accesses a set of training pairs of historical infrastructure requirement and historical LIT graph that satisfies the historical infrastructure requirement. Then, the infrastructure production method 200 iteratively feeds the pairs of historical infrastructure requirement and historical LIT graph into the first LLM to teach the first LLM the mapping between the pair. And, the infrastructure production method 200 updates or adjusts parameters of the first LLM to reduce error or loss between (a) the LIT graphs generated by the first LLM from the historical infrastructure requirements and (b) the historical LIT graphs corresponding to the historical infrastructure requirements.

In one embodiment, infrastructure production method 200 presents the LIT in a user interface as a LIT graph for user validation and approval before proceeding to second stage 310. In one embodiment, infrastructure production method 200 validates the translation of the infrastructure requirements into the LIT graph with an additional LLM that is trained to detect errors in logical infrastructure topologies. In one embodiment, either the user or the additional LLM may supply corrective updates to the LIT. In response to receiving the corrective updates, infrastructure production method 200 adds the corrected LIT graph and the associated infrastructure requirements to the training dataset for the first LLM model. Then, infrastructure production method initiates a further iteration of the training process for the first LLM model (above) to retrain the first LLM model to improve accuracy of LIT generation.

At a second stage 310, the translate the infrastructure requirements and the LIT into the PIT using a second LLM that is trained to generate physical infrastructure topologies. In one embodiment, infrastructure production method 200 loads (or otherwise accesses) the second LLM, dynamically generates a prompt for generation of the PIT from the infrastructure requirements and the LIT, submits the prompt to the first LLM, and then captures the response from the first LLM.

In one embodiment, the prompt for generation of the PIT is dynamically generated by loading and populating a template prompt for PIT generation. The template prompt for PIT generation includes (i) infrastructure requirements, (ii) the text description of the LIT (e.g., the graph representation language text that describes the LIT), and (iii) graph representation language as populatable fields. The template prompt for PIT generation includes instructions to generate a PIT graph in the graph representation language from the infrastructure requirements and the LIT. For example, the template prompt for PIT generation may be something like “Generate a physical infrastructure topology graph in [GraphRepresentationLanguage] for the following infrastructure requirements: [InfrastructureRequirements], based on the following logical infrastructure topology graph: [LogicalInfrastructure TopologyGraph].”

Similar to the template prompt for LIT generation above, the template prompt for PIT generation includes populatable fields: [GraphRepresentationLanguage] for specifying a graph representation language for the PIT graph; and [InfrastructureRequirements] for providing the infrastructure requirements to be satisfied by the PIT graph. The template prompt for PIT generation also includes a further populatable field, [LogicalInfrastructure TopologyGraph], for providing the previously-generated LIT graph from the first stage 305 above. In one embodiment, the [InfrastructureRequirements] inserted into the template prompt is the text of infrastructure requirements provided as input to the infrastructure production system (such as infrastructure requirements 130). In one embodiment, before inclusion in the template prompt, the text of the infrastructure requirements is filtered to remove the functional requirements (which were used to generate the LIT) and retain the non-functional requirements (which are used to generate a PIT). In one embodiment, the template prompt may state that the PIT graph should be generated “for the non-functional requirements described in the following infrastructure requirements: [InfrastructureRequirements].”

Infrastructure production method 200 submits the populated prompt for generation of the PIT to the second LLM, for example by invoking the PIT generation function of the second LLM via a corresponding API endpoint for the second LLM. The second LLM tokenizes and embeds the prompt for generation of the PIT, including the infrastructure requirements, LIT graph, and selected graph representation language. The attention mechanisms of the second LLM differ in focus from those of the first LLM. The second LLM applies attention mechanisms to focus on relevant parts of the infrastructure requirements that inform the design of the PIT. For example, the attention mechanism considers both the logical design provided by the LIT graph and physical features as laid out in the infrastructure requirements. The physical features considered by the attention mechanism of the second LLM might include (but are not limited to) hardware specifications, network configurations, routing, IP addressing, and resource allocation. The second LLM applies its trained understanding of logical infrastructure design principles to synthesize the relevant parts of the infrastructure requirements and the LIT into a text description of the PIT. For example, the second LLM generates a series of graph representation language tokens that describe a graph of the PIT.

Infrastructure production method 200 captures and stores the graph representation language expression of the PIT (for short, the “PIT graph text”) produced by the second LLM. The PIT graph text is thus expressed as a text data structure. For example, infrastructure production method reads the PIT graph text from an API endpoint of the second LLM, and writes the PIT graph text to a file, database, memory, or other storage to make the PIT graph text available for subsequent use.

In one embodiment, the second LLM is trained to generate physical infrastructure topologies using a second training dataset. The second training dataset includes corresponding triplets (sets of three) of historical infrastructure requirements, historical LIT graphs that are considered to satisfy the historical infrastructure requirements, and historical PIT graphs that are considered to satisfy the historical infrastructure requirements. In one embodiment, the corresponding triplets of historical infrastructure requirement, historical LIT graph, and historical PIT graph may be obtained from a database of previously implemented deployments of compute infrastructure. Thus, in one embodiment, the first and second training datasets may overlap, or, in one embodiment, even be a same training dataset. Where the second training dataset overlaps the first, the overlapping portion of the second training dataset includes in its triplets historical PIT graphs that correspond to pairs of historical LIT graph and infrastructure requirements from the first training dataset. In other words, the first training dataset includes triplets that include pairs of historical LIT graph and infrastructure requirements that are used for training of the first LLM, and further includes historical PIT graphs which are disregarded or otherwise not used for training of the first LLM, and are used for training the second LLM.

In one embodiment, to train the second LLM to generate physical infrastructure topologies based on infrastructure requirements and a LIT graph, the infrastructure production method 200 accesses training sets of historical infrastructure requirement, historical LIT graph that satisfies the historical infrastructure requirement, and historical PIT graph that satisfies the historical infrastructure requirement. Then, the infrastructure production method 200 iteratively feeds sets of historical infrastructure requirement, historical LIT graph, and historical PIT graph into the second LLM to teach the second LLM the mappings between infrastructure requirement, LIT graph, and PIT graph. And, the infrastructure production method 200 updates or adjusts parameters of the second LLM to reduce error or loss between (a) the PIT graphs generated by the second LLM from the historical infrastructure requirements and corresponding historical LIT graphs, and (b) the historical PIT graphs corresponding to the historical infrastructure requirements.

In one embodiment, generally for both the first LLM for generating the LIT and the second LLM for generating the PIT, the infrastructure production system trains its LLMs on a broad dataset that includes a variety of infrastructure designs, logical topologies, and physical infrastructure topologies. In one embodiment, the infrastructure production system employs training data (historical data) from a variety of sources to train the LLMs.

The training data may be manually curated, in which experts select sets of corresponding infrastructure requirement, LIT, and PIT. The experts select training data that are deemed to satisfy one or more thresholds for quality (such as being correct).

The training data may be drawn from databases of corresponding infrastructure requirement, LIT, and PIT for existing deployment configurations. For example, a cloud provider or cloud client may maintain a database of infrastructure solutions-including infrastructure requirement, LIT, and PIT for the solution—that are known to be correct, and which therefore provide a rich source of training data.

The training data can also be derived from existing cloud deployments. For example, configurations of existing cloud infrastructure may be analyzed to reverse-engineer corresponding PIT, LIT, and infrastructure requirement for the existing cloud infrastructure, which may then be used to train the LMMs.

After initial training, the LLM(s) training may be updated by fine-tuning to adjust the model based on feedback from validation processes, in which errors in generated topologies are identified and corrected. Additional detail on LLM training is provided elsewhere herein, for example under the heading “Example LLM Training”.

In one embodiment, infrastructure production method 200 presents the physical infrastructure topology in a user interface as a PIT graph for user validation and approval before proceeding to block 220. For example, the PIT graph may be displayed in a manner similar to that shown and described below with reference to FIG. 6. In one embodiment, infrastructure production method 200 validates the translation of the infrastructure requirements and LIT graph into a PIT graph using an additional LLM that is trained to detect errors in physical infrastructure topologies. In one embodiment, either the user or the additional LLM may supply corrective updates to the PIT. In response to receiving the corrective updates, infrastructure production method 200 adds the corrected PIT graph and the associated LIT graph and infrastructure requirements to the training dataset for the second LLM model. Then, infrastructure production method 200 initiates a further iteration of the training process for the second LLM model (above) to retrain the second LLM model to improve accuracy of PIT generation. Additional detail on graph validation is provided elsewhere herein, for example under the heading “Example Generated Topology Graph Validation”.

Referring again to FIG. 2, in block 215, infrastructure production method 200 accepts infrastructure requirements that are in human language form or format as input, and generates as output a graph of a PIT. The PIT graph of physical infrastructure topology (and intermediate LIT graph of logical infrastructure topology) may be described in a graph representation language. Thus, in one embodiment the PIT graph (and intermediate LIT graph) may be output as an ordered series of tokens of a graph representation language.

Various graph representation languages may be appropriate for outputting the graph, including but not limited to: JSON-Graph, graph modeling language (GML), GraphML, Graphviz DOT, trivial graph format (TGF), and resource description framework (RDF). In one embodiment, the first and second LLMs are trained specifically to generate graphs in one graph representation language. In this case, when generating graphs in another graph representation language, alternative versions of the first and second LLMs are used which have been trained to generate graphs in the other graph representation language. In one embodiment, the first and second LLMs are trained to generate graphs in more than one language. In this case, the first and second LLMs generate output in a graph representation language specified in a prompt to the first and second LLMs.

In one embodiment, the steps of block 215 are performed by topology generator 110. At the conclusion of block 215, infrastructure production method 200 has generated a PIT, which may be converted into an executable deployment specification. Processing continues to block 220.

At block 220, infrastructure production method 200 converts the PIT into an executable deployment specification. For example, design method 200 may execute a script or other tool that is configured to map the PIT components to a syntax of the deployment specification (such as YAML or HCL). Infrastructure production method 200 thus automates adaptation of the PIT to an executable configuration or executable setup tasks. Infrastructure production method 200 thus transposes PIT into a set of instructions that can be autonomously carried out by a computer to set up and deploy the compute infrastructure described in the infrastructure requirements.

In one embodiment, the tool for conversion of the PIT to the deployment specification may be referred to as an IaC (infrastructure-as-code) specification generator. At a high level, operation of the IaC specification generator varies based on the destination tool. For example, to convert the PIT to a YAML Ansible playbook, the IaC specification generator maps the PIT components to the YAML syntax for tasks and roles that is executable by Ansible. Or, for example, to convert the PIT to an HCL Terraform configuration file, the IaC specification generator maps the PIT components to the HCL syntax for declarative provisioning that is executable by Terraform.

In one embodiment, infrastructure production method 200 operates an IaC specification generator to convert the PIT into an executable deployment specification. The infrastructure production method 200 receives and parses the input PIT graph to identify the components of the topology. The parsing recognizes the components based on predefined attributes associated with components. Attributes of components are specific characteristics or properties associated with individual components in the topology that provide details about the component such as type, size, location, or function of the component within the compute infrastructure. Examples of attributes include type of a component (e.g., bastion, load balancer, compute instance, database, subnet, gateway, etc.), unique identifier or other resource name given to a component, and configuration details that are related to a component.

When parsing the PIT graph, infrastructure production method 200 examines the graph elements for attributes that identify what a component is and how it is connected. Infrastructure production method 200 recognizes components by matching attributes using a predefined schema or set of rules to match attributes to pre-defined component types. For example, a component with attributes such as “type: virtual_machine” and “cpu_count: 4” would be recognized as a virtual machine (compute instance) that is to be added to the deployment specification. And, for example, a component with attributes such as “type: network” and an “ip_range” would be recognized as a network or sub-network that is to be configured by the deployment specification. Such recognition may be performed by evaluating regular expressions, or other Boolean matching. In this way, based on recognition of attributes, infrastructure production method 200 can classify the components that correspond to specific resource types in the deployment specification.

Once the components of the PIT graph are classified by type, infrastructure production method 200 assembles the deployment specification. The deployment specification is written in infrastructure code (e.g., HCL or YAML code), which is used to define and automate deployment of infrastructure. In one embodiment, infrastructure production method 200 generates configuration blocks of infrastructure code for each component. In one embodiment, the infrastructure code declaratively defines the compute infrastructure that is to be created by execution of the infrastructure code, as is the case with HCL. In one embodiment, the infrastructure code specifies the steps to be performed by execution of the code which will result in creation of the compute infrastructure, such as is the case with YAML.

Infrastructure production method 200 then assembles the configuration blocks into a deployment specification file (e.g., Terraform configuration file or Ansible playbook). The blocks are placed into the deployment specification file in a coherent order, that, when executed, will result in a compute infrastructure that conforms to the PIT graph. In one embodiment, related components are placed into the deployment specification file in positions that ensure dependencies are properly handled (e.g., ensuring subnetworks are defined before compute instances that used the subnetworks).

In one embodiment, to generate the configuration blocks, infrastructure production method 200 accesses and retrieves configuration templates or patterns of infrastructure code that correspond to the type of the components. Infrastructure production method 200 populates the configuration templates for the individual components of the PIT graph based on the specific attributes of the individual components to produce the configuration blocks for the individual components. For example, a number of CPUs, amount of memory, and disk size specified for an individual compute instance in the PIT graph would be used to populate the corresponding fields for the compute instance in the configuration block. The infrastructure production method then inserts or adds the completed configuration blocks to the deployment specification. Once all components of the PIT graph are added to the deployment specification, the deployment specification is completed.

Infrastructure production method 200 then stores completed deployment specification is then stored for subsequent execution. For example, the finalized deployment specification is written to a file. The file may be, for example a *.yml file for an Ansible YAML playbook, or a *.tf file for a Terraform HCL configuration file.

In one embodiment, the steps of block 220 are performed by specification generator 115. At the conclusion of block 220, infrastructure production method 200 has generated an executable deployment specification file, which may be executed by an infrastructure deployment tool, such as an IaC tool like Terraform or an automation framework and configuration management tool like Ansible. Processing continues to block 225.

At block 225, infrastructure production method 200 executes the deployment specification to automatically configure a target computer system to have the compute infrastructure described by the infrastructure requirements. For example, infrastructure production method 200 may execute the deployment specification to automatically configure infrastructure of the computing system as described by the infrastructure requirements. In one embodiment, infrastructure production method 200 takes the deployment specification as input; parses the deployment specification to determine the declarations or sequence of actions for provisioning and configuring in the target computing system the infrastructure that is described in the deployment specification; executes the declarations or sequence of actions to provision and configure the infrastructure in the target computing system, and thereby outputs a fully configured target computer system that matches the compute infrastructure outlined in the infrastructure requirements. Infrastructure production method 200 thus uses the deployment specification to automatically set up the target system in a way that conforms to the infrastructure requirements.

In one embodiment, infrastructure production method 200 initializes an orchestration engine for executing the deployment specification. For example, infrastructure production method 200 loads the IaC tools and libraries used to interpret and execute the deployment specification. And, infrastructure production method 200 configures access to the target computing system, for example providing credentials for the target computing system, establishing network access to the target computing system, and obtaining authorization permissions to interact with the target computing system.

In one embodiment, infrastructure production method 200 loads the deployment specification. For example, infrastructure production method 200 reads the deployment specification (e.g., a YAML or HCL file) from its location in storage. Then, infrastructure production method 200 parses the deployment specification to identify the infrastructure components (e.g., virtual machines, networks, storage, and security groups) that are to be provisioned and configured. And, infrastructure production method 200, generates a process or execution strategy that specifies steps that achieve the specified state of infrastructure in the target environment.

In one embodiment, infrastructure production method 200 then sets up the specified state of infrastructure in the target computing system. For example, infrastructure production method 200 provisions the infrastructure components in the target computing system, for example allocating resources (e.g., providing the specified CPU, RAM, and storage of a given virtual machine) and applying network settings and access controls. Once the components are provisioned, infrastructure production method 200 applies additional configuration tasks (if any) that are specified in the deployment specification, such as installing software, setting up services, and configuring application settings on the provisioned infrastructure.

Then, in one embodiment, infrastructure production method 200 grants the client network access to the provisioned and configured compute infrastructure in the target computing system. In one embodiment, infrastructure production method 200 returns one or more IP addresses, DNS names, and/or endpoint URLs for accessing the provisioned and configured compute infrastructure. In one embodiment, individual infrastructure components are directly addressable by IP address or DNS name. In one embodiment, discrete endpoint URLs are provided that are specific to particular services that are available in the provisioned and configured compute infrastructure, such as an endpoint for storage or for a database. In one embodiment, an API gateway provides a unified endpoint URL through which API requests are routed to services configured to handle the requests in the provisioned and configured compute infrastructure.

In one embodiment, the steps of block 225 are performed by orchestration engine 120. At the conclusion of block 225, infrastructure production method 200 has put into operation in the target environment a configuration of computing resources that was specified in the deployment specification. In this way, the compute infrastructure initially described in the infrastructure requirements is fully realized and made ready for use in the target computing system. In this manner, the design and deployment processes are made fully automatic. Processing continues to END block 230, where infrastructure production method 200 concludes.

### —Further Features of Infrastructure Production Method—

In one embodiment, translating the infrastructure requirements into the PIT (discussed at block 215) includes steps for translating the infrastructure requirements into an intermediate LIT prior to producing the PIT. As discussed above with reference to FIG. 3, the infrastructure production method 200 first translates the requirements into a LIT. The first translation is performed using a first LLM that is trained to generate logical infrastructure topologies. Then, the infrastructure production method 200 translates the infrastructure requirements and the LIT into the PIT. This second translation is performed using a second LLM that is trained to generate physical infrastructure topologies.

In one embodiment, translating the infrastructure requirements into the PIT (discussed at block 215) includes steps for displaying the LIT graph and PIT graph for user review and validation. For example, infrastructure production method 200 presents the LIT as a LIT graph for a first user approval before proceeding to translate the LIT into the PIT (at block 310). And, infrastructure production method 200 present the PIT as a PIT graph for a second user approval before proceeding to convert the PIT into the executable deployment specification (at block 220).

In one embodiment, the executable deployment specification (of blocks 220 and 225) is written in YAML code (for Ansible). Or, in one embodiment, the executable deployment specification is written in HCL code (for Terraform).

In one embodiment, infrastructure production method 200 further includes steps for training LLMs. For example, infrastructure production method 200 accesses a training set of associated training logical infrastructure topologies, training physical infrastructure topologies, and training infrastructure requirements for other computing infrastructure. And, infrastructure production method 200 trains one LLM of the one or more LLMs to generate the physical infrastructure topologies using the training physical infrastructure topologies, training logical infrastructure topologies, and training infrastructure requirements in the training set. In one embodiment, infrastructure production method 200 trains the first LLM to generate the logical infrastructure topologies using the training logical infrastructure topologies and training infrastructure requirements in the training set. And, infrastructure production method 200 trains the second LLM to generate the physical infrastructure topologies using the training physical infrastructure topologies, training logical infrastructure topologies, and training infrastructure requirements in the training set.

In one embodiment, infrastructure production method 200 further validates the translation using one or more further LLMs that are trained to detect errors in infrastructure topologies. For example, infrastructure production method 200 automatically validates the LIT with a third LLM that is trained to detect whether there exist errors in the LIT. And, infrastructure production method 200 automatically validates the PIT with a fourth LLM that is trained to detect whether there exist errors in the PIT.

In one embodiment, infrastructure production method 200 further includes steps to cause the LLMs for generating the LIT and PIT to be improved in response to detected errors. For example, in response to detection of an error in the LIT, infrastructure production method 200 automatically updates first training data for the first LLM with corrections to the error in the LIT, and re-trains the first LLM with the updated first training data. And, in response to detection of an error in the PIT, infrastructure production method 200 automatically updates second training data for the second LLM with corrections to the error in the PIT, and re-trains the second LLM with the updated second training data.

In one embodiment, translating the infrastructure requirements into the PIT (discussed at block 215) further includes representing the PIT as a collection of tokens in a graph representation language. For example, infrastructure production method 200 generates the LIT and the PIT as collections of tokens in a graph representation language. Thus, in one embodiment, translating the infrastructure requirements into a LIT further includes representing the LIT as a first collection of tokens in a graph representation language. And, in one embodiment, translating the infrastructure requirements and the LIT into a PIT further includes representing the PIT as a second collection of tokens in the graph representation language.

### —Context and Discussion of LLM-Generated Infrastructure Design—

In one embodiment, the infrastructure production system 100 uses a trained LLM to generate infrastructure designs, and automatically deploy the generated designs. The infrastructure designs include designs for both logical and physical infrastructure. In one embodiment, generating and deploying the infrastructure designs begins with the infrastructure production system 100 creating a logical infrastructure definition from infrastructure requirements. For example, infrastructure production system 100 creates a LIT graph using an LLM. The LIT graph serves as a representation of the infrastructure that is agnostic to underlying hardware. Then, the infrastructure production system 100 converts the logical infrastructure definition into a physical infrastructure definition using an LLM. For example, infrastructure production system 100 creates a PIT graph. The PIT graph details specific hardware and configurations that implement a design for the infrastructure.

In one embodiment, the infrastructure design process employs a shared LLM for both the generation of the LIT from infrastructure requirements, and generation of the PIT from the LIT and infrastructure requirements. In another embodiment, infrastructure design process employs dedicated LLMs for discrete stages of the process (requirements-to-logical and logical-to-physical), ensuring specialized handling at the separate stages. In one embodiment, the LLM dedicated to the second stage, logical-to-physical translation may be further specific to the cloud provider for the target computing environment: for example, the training data for training the second LLM may be limited to physical infrastructure configurations that are available from the cloud provider. Thus, in one embodiment, infrastructure production system 100 improves over existing infrastructure design and deployment processes by ensuring consistent generation of logical infrastructure for a given infrastructure requirement using a first LLM, while providing accurate and flexible conversion to environment-specific physical infrastructure.

Infrastructure production system 100 then further renders the physical infrastructure definition into a specific infrastructure code language used for infrastructure deployment, such as YAML code for use by an Ansible orchestration engine, or HCL code for use by a Terraform orchestration engine. The infrastructure code that is output is a set of executable instructions that can be deployed by an orchestration engine to create the physical infrastructure in a target computing system. Infrastructure production system 100 then runs the infrastructure code in a corresponding orchestration engine to configure the target computing system to have the physical computing infrastructure indicated by the infrastructure requirements.

In one embodiment, at the stages of the infrastructure production process, infrastructure requirements to LIT, LIT to PIT, and PIT to infrastructure code, there are validation processes to ensure that the generated designs and code are accurate and meet the expectations.

### —Example Infrastructure Design Process—

Logical infrastructure is an abstraction of physical infrastructure, generalized to the functional level. Thus, the logical infrastructure is independent of the hardware configurations and network configurations that implement the infrastructure. Logical infrastructure (or logical architecture) specifies the functional elements of the system. Physical infrastructure (or physical architecture) specifies further information: particular devices that the functional elements execute on.

FIG. 4 illustrates an example infrastructure design process 400 that is associated with LLM-based generation and deployment of designs for computing infrastructure. Infrastructure design process 400 includes three stages: a LIT generation stage 405, a PIT generation stage 410, and a deployment code generation stage 415.

At a high level, infrastructure design process 400 performs multiple steps for automatically producing an executable deployment specification from infrastructure requirements that are in human language form or format. First, infrastructure design process 400 inputs infrastructure requirements that are relevant to the LIT, LIT requirements 420. An example of infrastructure requirements is provided in Table 1 below. Second, infrastructure design process 400 produces a logical infrastructure design or topology, LIT graph 425. LIT graph 425 may be represented as a graph or a collection of textual tokens translatable to a graph. An example of a LIT graph generated from the infrastructure requirements of Table 1 is visualized as a graph in FIG. 5 and represented as a collection of tokens in Table 2 below. Third, infrastructure design process 400 enriches LIT graph 425 to a physical infrastructure design or topology, PIT graph 430. PIT graph 430, too, may be represented as a graph or a collection of textual tokens translatable to a graph. An example of a PIT graph generated from the infrastructure requirements of Table 1 and the LIT graph of Table 2 (and visualized in FIG. 5) is visualized as a graph in FIG. 6.

In one embodiment, infrastructure design process 400 relies on two LLMs. The first LLM, LIT LLM 435, is trained to translate infrastructure requirements (such as LIT requirements 420) into a LIT graph (such as LIT graph 425). The second LLM, PIT LLM 440 is trained to translate infrastructure requirements that are relevant to the PIT (such as PIT requirement 445), together with a LIT graph, into a PIT graph. Thus, the LIT graph 425 generated by LIT LLM 435 in LIT generation stage 405 serves as input to PIT LLM 440 in PIT generation stage 410.

In one embodiment, the infrastructure design system parses a set of infrastructure requirements that is input to identify portions of the infrastructure requirements that are relevant to generating LITs, LIT requirements 420. For example, the LIT requirements 420 that are extracted from the infrastructure requirements include information related to technology standards, high availability options, and security. And, the infrastructure design system parses the set of infrastructure requirements to identify portions that are relevant to generating PITs, PIT requirements 445. For example, the PIT requirements 445 include information related to routing and filtering among components, capacities of components, and security.

The LLMs 435, 440 convert the infrastructure requirements to tokens. For example, the string(s) of text that make up the infrastructure requirements is parsed to split the text into smaller units such as words, subwords, or characters, that represent basic elements of a language. In the case of the infrastructure requirements, the tokens are tokens of a human language, such as English.

Tokens are in turn translated to embeddings. To create the embeddings, the LLMs 435, 440 convert tokens of the infrastructure requirements into numerical vectors in a multi-dimensional space that captures their semantic meaning. The “semantic meaning” of the tokens refers to the underlying concepts or ideas conveyed by the tokens in view of context and relationships between the tokens. Example embedding models that may be used for embedding tokens include, but are not limited to Word2Vec, GloVe, FastText, BERT (Bidirectional Encoder Representations from Transformers), ELMo (Embeddings from Language Models), GPT (Generative Pre-trained Transformer), and Universal Sentence Encoder. Other embedding models, including domain-specific and proprietary embedding models may also be appropriate. LLMs 435, 440 may embed both tokens of human language and tokens of graph representation language.

Attention heads of the LLMs 435, 440 focus on specific context which influences the decision of adding chosen infrastructure resources to a generated topology graph 425, 430. In one embodiment, LLMs 435, 440 include an attention mechanism that determines importance of tokens when processing a sequence tokens using one or more attention heads. Attention heads determine importance of a token based on context—the various relationships of a token to concepts or other tokens in the sequence. Here, the attention heads of the LLMs 435, 440 serve to map input to particular infrastructure components by giving greater importance to specific tokens that correspond to components that are available for inclusion in an infrastructure. In one simple example, an example attention mechanism that is associated with adding a bastion host—a secure server for providing access using the SSH (secure shell) protocol—may give higher importance to tokens such as ‘SSH’ and ‘shell’. And, the example attention mechanism may assign lower importance to tokens such as ‘SSL’ and ‘socket’, because the secure sockets layer (SSL) protocol generally does not indicate that a bastion host is called for.

In LIT generation stage 405, the LIT LLM 435 operates to produce a LIT graph 425 that is valid. LIT LLM training 450 accesses one or more batches of LIT LLM training data 455. LIT LLM training 450 trains LIT LLM by updating a configuration of weights of LIT LLM 435 so as to cause LIT graphs produced by LIT LLM 435 from training infrastructure requirements to more closely match training LIT graphs corresponding to the training infrastructure requirements.

LIT requirements 420 are extracted from provided infrastructure requirements, and provided to the trained LIT LLM 435. The LIT requirements 420 are converted to tokens, embedded, and processed by LIT LLM 435 to generate LIT graph 425, which represents the LIT requirements 420 as a LIT.

The graph generation step for the infrastructure topologies (logical and physical) may be subjected to validation. LIT graph 425 is provided to LIT validation 470 to detect errors in LIT graph 425. In one embodiment, LIT validation 470 causes the LIT graph 425 to be displayed to a user for review, and accepts input of errors (if any) and corresponding corrections by the user. In one embodiment, LIT validation 470 presents LIT graph 425 to a further LLM for validation. This validation LLM is trained to accept a LIT graph and, in response, generate a list of errors (if any) and corresponding corrections to the errors. In either case, the errors and corresponding corrections may be captured, for example by parsing them out of the user input or response by the validation LLM, and then stored for future reference.

At decision block 472, the infrastructure design process 400 checks to see whether LIT graph 425 is valid, for example by checking to see if there are no errors. If there are no errors in LIT graph 425, LIT graph 425 is valid (block 472: YES), and the LIT generation stage 405 completes and infrastructure design process 400 proceeds to PIT generation stage 410. If there is one or more errors in LIT graph 425, LIT graph 425 is invalid (block 472: NO), and LIT generation stage 405 processes the LIT graph validation errors 474. The corrections collected during LIT validation 470 may then be used to re-train the LIT LLM 435 to mitigate the errors. LIT generation stage 405 may then be retried with the re-trained LIT LLM.

In one embodiment, retraining of the LIT LLM 435 may be performed by prompt engineering. Here, the corrections are provided in prompts to the LIT LLM 435. For example, the correction may be a human language statement of a rule, a human language statement modifying a rule, or a human language statement canceling a rule. The statement may then be dynamically generated or assembled into in a prompt to the LIT LLM 435, such as “In the topologies that you generate in the future, make sure to [statement].” The dynamically generated prompt may then be automatically injected into the LIT LLM 435 through a chat endpoint, thereby adjusting the behavior of the LIT LLM 435.

In one embodiment, retraining of the LIT LLM 435 may be performed by fine tuning. Here, the corrections are provided as a revised or edited version of LIT graph 425 which has no errors. The pair of the revised LIT graph and the infrastructure requirements are input as LIT LLM training data 455 into LIT LLM training 450, which retrains the LIT LLM to generate a LIT graph that conforms to the revised version of LIT graph 425 from the infrastructure requirements, thereby adjusting the behavior of the LIT LLM 435.

In PIT generation stage 410, the PIT LLM 440 operates to produce a PIT graph that is valid by performing steps similar to those in LIT generation stage 405. In one embodiment, PIT LLM training 460 accesses PIT LLM training data 465, and trains PIT LLM 440 to cause PIT graphs produced by PIT LLM 440 from training infrastructure requirements and corresponding training LIT graphs to more closely match training PIT graphs that correspond to the training infrastructure requirements and LIT graphs. PIT requirements 445 are extracted from the provided infrastructure requirements, tokenized, embedded, and processed by PIT LLM 440 to produce PIT graph 430. PIT validation 475 captures errors in PIT graph 430 (in a manner similar to that discussed above for LIT validation 470), and, where errors are detected, collects corrections to the errors. At block 477, where there are no errors in PIT graph 430, PIT graph 430 is valid (block 477: YES), and the PIT graph 430 is ready for translation into a deployment specification, such as in Ansible YAML code or Terraform HCL code. Where there are one or more errors in PIT graph 430, PIT graph 430 is invalid, (block 477: NO), and the PIT graph validation errors 479 (including their associated solutions) may then be used to re-train the PIT LLM 440. PIT generation stage may then be retried with the re-trained LIT LLM.

The PIT LLM 440 produces a PIT graph 430. The resulting PIT graph 430 includes connectivity aspects, such as network isolation. However, to complete the physical infrastructure design, the vertices of the PIT graph 430 may include additional properties, such as routing, filtering, switching, IP address ranges, and capacity specifications for compute and storage vertices. This additional information, PIT requirements 445, is included as part of the infrastructure requirements input. At the completion of PIT generation stage 410, the PIT requirements 445 are incorporated in or otherwise associated with the PIT graph 430.

In deployment code generation stage 415, the PIT graph 430 is used to generate a deployment specification. The deployment specification may be embodied, e.g., in YAML code (interpretable by Ansible), or in HCL code (interpretable by Terraform). Where the target computing system is a cloud or on-premises provider 480 that is managed by or otherwise configurable by Ansible, deployment code generation stage 415 provides PIT graph 430 to the cloud or on-premises provider 480 for conversion into YAML Ansible deployment code 485. Where the target computing system is a cloud provider 490 that is managed by or otherwise configurable by Terraform, deployment code generation stage 415 provides PIT graph 430 to the provider for conversion into HCL Terraform deployment code 495.

### —Example LLM Training—

In one embodiment, the LIT LLM 435 and PIT LLM 440 each undergo a training process. LIT LLM training 450 trains LIT LLM 435 to generate LIT graphs from infrastructure requirements based on a first training dataset of training materials, LIT LLM training data 455. PIT LLM training 460 trains PIT LLM 465 to generate PIT graphs from LIT graphs and infrastructure requirements that correspond to (i.e., result in) the LIT graphs based on a second training dataset of training materials, PIT LLM training data 465.

In one embodiment, LIT LLM training 450 for the LIT LLM 435 and PIT LLM training 460 for PIT LLM 440 is based on an accumulation of previously defined (historical) LIT and PIT graphs that are accepted as valid. These historical LIT and PIT graphs may be represented as collections of tokens (i.e., in a graph representation language). The training materials (LIT LLM training data 455) for LIT LLM 435 include pairs of infrastructure requirements and corresponding LIT graphs resulting from the infrastructure requirements. The training materials (PIT LLM training data 465) for PIT LLM 440 include triplets of infrastructure requirements, the corresponding resulting LIT graphs, and the corresponding resulting PIT graphs.

During the training process, parameters related to tokenization, size of the vector embeddings, and number of attention heads may be tuned or adjusted to improve results.

### —Example of LLM-Generated Infrastructure Design—

Infrastructure Requirements. In one embodiment, as discussed at block 210 above, the infrastructure design process starts with a specification of infrastructure requirements—including functional, operational, security, and other requirements—as input. Table 1 below is an example of infrastructure requirements for infrastructure. (The line numbers of Table 1 are provided for convenience of reference herein, and are not part of the infrastructure requirements.)

TABLE 1

| 01 | Produce infrastructure topology for: | |
|---|---|---|
| 02 | Infrastructure Functional requirements (what): | |
| 03 | - | application provides web UI and API access, |
| 04 | - | publicly available / access restricted to IP address ranges |
| 05 | - | with DNS name: acme.mydns.com, |
| 06 | - | two load balancers separate for web UI and API access, |
| 07 | Operational requirements (how): | |
| 08 | - | reliability/SLA: 99,9% |
| 09 | - | HA: yes |
| 10 | - | capacity (users): 100 |
| 11 | - | response time: 20mS |
| 12 | - | user geographical distribution: (60% Illinois, 35% New York, 5% |
| 13 | | Australia) |
| 14 | - | recovery time objectives: 4hours, |
| 15 | - | recovery point objectives: 1hour, |
| 16 | - | secure SSH access to all the compute nodes using bastion technology, |
| 17 | - | bandwidth requirements: 10MB/s |
| 18 | Security requirements: | |
| 19 | - | SSL enabled front-end, |
| 20 | - | internal SSL encryption enabled, |
| 21 | - | access to Internet from internal hosts allowed only to specified external |
| 22 | | IP addresses: |
| 23 | - | 123.22.33.44 port: 443 |
| 24 | - | 36.23.22.147 port: 8080 |
| 25 | - | protocols to be implemented: |
| 26 | - | HTTPS, |
| 27 | Technology requirements: | |
| 28 | - | application is based on Java (or python / go), |
| 29 | | |
| 30 | - | use WebLogic (use Containerization / use OracleDB / do not use |
| | | Docker). |

LIT Graph Created Based on Infrastructure Requirements. In one embodiment, as discussed above at block 305, the infrastructure design process produces a LIT graph based on infrastructure requirements. FIG. 5 illustrates an example LIT graph 500 that is associated with LLM-based generation and deployment of designs for computing infrastructure. LIT graph 500 is an example of a LIT graph generated as an intermediate step from the infrastructure requirements of Table 1. In one embodiment, LIT graph 500 is generated by a LIT LLM, such as is shown and described with reference to infrastructure design system 400, infrastructure production system 100, and with reference to block 305. LIT graph 500 includes representations of infrastructure components at a logical level.

LIT graph 500 includes Bastion1 505. Bastion1 505 is generated by LIT LLM at least in part in response to the infrastructure requirements at line 16 of Table 1. LIT graph 500 includes two load balancers, LB1 510 and LB2 515. LB1 510 and LB2 515 are generated by LIT LLM at least in part in response to the infrastructure requirements at line 06 of Table 1. LIT graph 500 includes three compute instances, Compute1 520, Compute2 525, and Compute3 530. Compute1 520, Compute2 525, and Compute3 530 are generated by LIT LLM at least in part in response to the operational requirements at lines 07-17 of Table 1, and especially by the user geographical distribution at lines 12-13. The compute instances (Compute1 520, Compute2 525, and Compute3 530) each have an associated boot volume (bootvol1 535, bootvol2 540, and bootval3 545), and an associated storage volume (vol1 550, vol2 555, and vol3 560). The boot volumes and storage volumes are generated by LIT LLM at least in part by inference from the compute instances. LIT graph 500 includes a database DB1 565 and a database storage volume storagedb1 570. DB1 565 and storagedb1 570 are generated by the LIT LLM at least in part in response to the technology requirements at line 29 of Table 1.

Bastion1 505 is connected to Compute1 520, Compute2 525, Compute3 530, and DB1 565, as indicated by the infrastructure requirements at line 16 of Table 1. Load balancers LB1 510 and LB2 515 are connected to Compute1 520, Compute2 525, Compute3 530, as indicated by the function of load balancers and the infrastructure requirements at line 06 of Table 1. The compute instances, Compute1 520, Compute2 525, and Compute3 530, are connected respectively to their associated boot volumes bootvol1 535, bootvol2 540, and bootval3 545, and to their associated storage volumes vol1 550, vol2 555, and vol3 560, as inferred from the structure of compute instances. The compute instances, Compute1 520, Compute2 525, and Compute3 530, are connected to DB1 565, as inferred from the purpose of a database and the infrastructure requirements at line 29 of Table 1 Database DB1 565 is connected to database storage volume storagedb1 570, as inferred from the structure of databases.

Example LIT Graph Tokenization for LLM. A graph represented as textual tokens could appear as shown in Table 2 below. Table 2 shows one example representation of the LIT graph 500 of FIG. 5 in an example graph representation language. (Note that this example graph representation language is an example used for illustrative purposes, and may be replaced with any of the other graph representation languages listed herein.) There are many ways to represent the information of the LIT graph in tokens of a graph representation language, none of which is more preferable than another, so long as it enables representation of a graph as a series of textual tokens. (The line numbers of Table 2 are provided for convenience of reference herein, and are not part of the infrastructure requirements.)

TABLE 2

| | |
|---|---|
| 01 | LIT[ |
| 02 | bastion[bastion1], |
| 03 | compute[compute1, compute2, compute3], |
| 04 | db[db1], |
| 05 | storage[bootvol1, bootvol2, bootvol3, vol1, vol2, vol 3], |
| 06 | storagedb[storagedb1], |
| 07 | lbr[lb1, lb2], |
| 08 | connections[ |
| 09 | NtoN([lb1, lb2], [compute1, compute2, compute3]), |
| 10 | 1to1([compute1, compute2, compute3], [bootvol1, bootvol2, bootvol3]), |
| 11 | 1to1([compute1, compute2, compute3, db1], [vol1, vol2, vol3, storagedb1]), |
| 12 | 1toN(bastion1, [compute1, compute2, compute3, db1]), |
| 13 | 1toN(db1, [compute1, compute2, compute3]) |
| 14 | ] |
| 15 | ] |

Lines 02-07 of Table 2 represent the components of the LIT graph using text tokens of graph representation language. Lines 08-14 of Table 2 represent connections between components of the LIT graph using text tokens of graph representation language.

PIT Graph Created Based on LIT Graph and Infrastructure Requirements. In one embodiment, as discussed above at block 310, the infrastructure design process produces a PIT graph based on infrastructure requirements and a LIT graph generated from the infrastructure requirements. FIG. 6 illustrates an example PIT graph 600 that is associated with LLM-based generation of designs for computing infrastructure. PIT graph 600 is an example of a PIT graph generated from the infrastructure requirements of Table 1 and LIT graph 500 as expressed in the text of Table 2. In one embodiment, PIT graph 600 is generated by a PIT LLM, such as is shown and described with reference to infrastructure design system 400, infrastructure production system 100, and with reference to block 310. PIT graph 600 includes representations of infrastructure components at a physical level.

PIT graph 600 includes nodes for infrastructure components that were generated for LIT graph 500 that are also components at the physical level. PIT graph 600 includes Bastion1 505. PIT graph 600 includes load balancers LB1 510 and LB2 515 PIT graph 600 includes compute instances Compute1 520, Compute2 525, and Compute3 530. PIT graph 600 includes database DB1 565.

PIT graph 600 also includes nodes for infrastructure components that were not generated for LIT graph 500. PIT graph 600 includes sub-networks Subnet1 605 and Subnet2 610. PIT graph 600 includes Internet gateway IGW1 615 and Internet 620.

Note that in the PIT graph, nodes have multiple properties or characteristics associated with them. For example, there may be types of nodes and corresponding standard sets of node characteristics. For instance, a compute type of element would have the number of OCPUs and the amount of memory. Or, for instance, a load balancer would, instead, have IP and port, SSL certificate, listeners, backend set(s), etc.).

Example PIT Graph Tokenization for LLM. A PIT graph represented as textual tokens could appear as shown in Table 3 below. Table 3 shows one example representation of the PIT graph 600 of FIG. 6 in graph representation language. The PIT graph includes a representation of the properties of the nodes as text tokens in the graph representation language. (The line numbers of Table 3 are provided for convenience of reference herein, and are not part of the infrastructure requirements.)

TABLE 3

| | |
|---|---|
| 01 | PIT[ |
| 02 | bastion[bastion1], |
| 03 | compute[compute1, compute2, compute3], |
| 04 | db[db1], |
| 05 | lbr[lb1, lb2], |
| 06 | subnet[subnet1, subnet2], |
| 07 | gateway[igw1], |
| 08 | internet[internet], |
| 09 | connections[ |
| 10 | Nto1([lb1, lb2], subnet1, unidirectional), |
| 11 | 1toN(subnet1, [compute1, compute2, compute3], unidirectional), |
| 12 | Nto1([compute1, compute2, compute3], subnet2, bidirectional), |
| 13 | 1to1(bastion1, subnet2, bidirectional), |
| 14 | 1to1(subnet2, db1, bidirectional), |
| 15 | 1to1(subnet2, igw1, bidirectional), |
| 16 | 1to1(igw1, internet, unidirectional) |
| 17 | ] |
| 18 | properties[ |
| 19 | bastion 1(type=standard, access=internet), |
| 20 | [compute1, compute2, compute3](ocpu=4, memory=32, boot_size=200), |
| 21 | db1(ocpu=4, storage=100, rac_enabled=yes, secure_connection=yes), |
| 22 | [lb1, lb2](listener(ip=external, port=443, ssl=yes, ssl_cert=, |
| 23 | dns=api.came.mydns.com), backend_set(ssl=yes, port={weblogicssl})), |
| 24 | subnet1(ip_subnet=192.168.200.0/24, secrules(ingress(from={internet}, |
| 25 | to={lbrs}, port=443), egress(from={all_loadbalancers}, to={all_compute}, |
| 26 | port={weblogic_ssl}))), |
| 27 | subnet2(ip_subnet=192.168.20.0/24, secrules(ingress(from={bastion}, |
| 28 | to={all}, port=22, type=allow), ingress(from={all_loadbalancers}, to={all}, |
| 29 | port={weblogic_ssl}), ingress(from={all}, to={database}, port=1521), |
| 30 | egress(ssl=yes, port={weblogic_ssl}))), |
| 31 | igw1(type=standard), |
| 32 | ] |
| 33 | ] |

Lines 02-08 of Table 3 represent the components of the PIT graph using text tokens of graph representation language. Lines 09-17 of Table 3 represent connections between components of the PIT graph using text tokens of graph representation language. Lines 18-32 of Table 3 represent the properties or characteristics of the of the physical infrastructure components.

### Example Advantages

Advantageously, in an improvement over existing infrastructure design and deployment processes, the separation of physical infrastructure definition and conversion to code from the initial logical infrastructure definition process enables infrastructure production system 100 to function across differing cloud environments. This enables a single logical infrastructure to be translated into different physical infrastructures and automatically deployed to different physical environments, each of which may vary depending on the cloud provider for the target computing system. Accordingly, infrastructure production system 100 may be used to automate infrastructure design and deployment to a wide variety of public cloud providers, including Oracle Cloud, Amazon Web Services, Microsoft Azure, Google Cloud Platform, IBM Cloud, as well as to private, on-premises (and hybrid) cloud solutions such as Oracle Cloud at Customer, VMware, Microsoft Azure Stack, IBM Cloud Private, Red Hat OpenShift, and OpenStack.

In another advantageous improvement, the infrastructure production system 100 employs dynamic generation of prompts to the LLMs based on population of template prompts. This standardizes inputs in a manner that ensures consistency in the process of designing LITs and PITs, and in the infrastructure code that is generated from them.

In one embodiment, the infrastructure production system improves over manual processes for design and deployment of compute infrastructure in a variety of ways. For example, the infrastructure production system provides consistent output that reduces errors, such as misconfigurations or overlooked dependencies that are common in manual processes. And, in one embodiment, the infrastructure production system may operate at or near real-time, moving from infrastructure requirements to deployment in minutes, rather than days or weeks, which is particularly advantageous to satisfy just-in-time deployment in a dynamic demand environment. Also, in one embodiment, because it employs LLMs for topology generation, the infrastructure production system can consider a vast array of parameters, dependencies, and constraints simultaneously, in a manner that is impossible for manual processes. Further, in one embodiment, the infrastructure production system is scalable to handle numerous and varied infrastructure design tasks simultaneously, in parallel, without loss of quality or speed.

### —Cloud or Enterprise Embodiments—

In one embodiment, the present system (such as infrastructure production system 100) is a computing/data processing system including a computing application or collection of distributed computing applications for access and use by other client computing devices that communicate with the present system over a network. The applications and computing system may be configured to operate with or be implemented as a cloud-based network computing system, an infrastructure-as-a-service (IAAS), platform-as-a-service (PAAS), or software-as-a-service (SAAS) architecture, or other type of networked computing solution.

In one embodiment the present system provides at least one or more of the functions disclosed herein and a graphical user interface to access and operate the functions. In one embodiment, infrastructure production system 100 is a centralized server-side application that provides at least the functions disclosed herein and that is accessed by many users by way of computing devices/terminals communicating with the computers of infrastructure production system 100 (functioning as one or more servers) over a computer network. In one embodiment infrastructure production system 100 may be implemented by a server or other computing device configured with hardware and software to implement the functions and features described herein.

In one embodiment, the components of infrastructure production system 100 may be implemented as sets of one or more software modules executed by one or more computing devices specially configured for such execution. In one embodiment, the components of infrastructure production system 100 are implemented on one or more hardware computing devices or hosts interconnected by a data network. For example, the components of infrastructure production system 100 may be executed by network-connected computing devices of one or more computing hardware shapes, such as central processing unit (CPU) or general-purpose shapes, dense input/output (I/O) shapes, graphics processing unit (GPU) shapes, and high-performance computing (HPC) shapes.

In one embodiment, the components of infrastructure production system 100 intercommunicate by electronic messages or signals. These electronic messages or signals may be configured as calls to functions or procedures that access the features or data of the component, such as for example application programming interface (API) calls. In one embodiment, these electronic messages or signals are sent between hosts in a format compatible with transmission control protocol/internet protocol (TCP/IP) or other computer networking protocol. Components of infrastructure production system 100 may (i) generate or compose an electronic message or signal to issue a command or request to another component, (ii) transmit the message or signal to other components of infrastructure production system 100, (iii) parse the content of an electronic message or signal received to identify commands or requests that the component can perform, and (iv) in response to identifying the command or request, automatically perform or execute the command or request. The electronic messages or signals may include queries against databases. The queries may be composed and executed in query languages compatible with the database and executed in a runtime environment compatible with the query language.

In one embodiment, remote computing systems may access information or applications provided by infrastructure production system 100, for example through a web interface server. In one embodiment, the remote computing system may send requests to and receive responses from infrastructure production system 100. In one example, access to the information or applications may be effected through use of a web browser on a personal computer or mobile device. In one example, communications exchanged with infrastructure production system 100 may take the form of remote representational state transfer (REST) requests using JavaScript object notation (JSON) as the data interchange format for example, or simple object access protocol (SOAP) requests to and from XML servers. The REST or SOAP requests may include API calls to components of infrastructure production system 100.

### —Software Module Embodiments—

In general, software instructions are designed to be executed by one or more suitably programmed processors accessing memory. Software instructions may include, for example, computer-executable code and source code that may be compiled into computer-executable code. These software instructions may also include instructions written in an interpreted programming language, such as a scripting language.

In a complex system, such instructions may be arranged into program modules with each such module performing a specific task, process, function, or operation. The entire set of modules may be controlled or coordinated in their operation by an operating system (OS) or other form of organizational platform.

In one embodiment, one or more of the components described herein are configured as modules stored in a non-transitory computer readable medium. The modules are configured with stored software instructions that when executed by at least a processor accessing memory or storage cause the computing device to perform the corresponding function(s) as described herein. In one embodiment, non-transitory computer-readable media may include stored thereon computer-executable instructions for performing the modules or the functions or the logic described herein.

### —Computing Device Embodiment—

FIG. 7 illustrates an example computing system 700 that is configured and/or programmed as a special purpose computing device(s) with one or more of the example systems and methods described herein, and/or equivalents. The example computing device may be a computer 705 that includes at least one hardware processor 710, a memory 715, and input/output ports 720 operably connected by a bus 725. In one example, the computer 705 may include LLM-based infrastructure production logic 730 configured to facilitate LLM-based generation and deployment of designs for computing infrastructure, similar to the logic, systems, methods, and other embodiments shown in and described with reference to FIGS. 1-6.

In different examples, the logic 730 may be implemented in hardware, one or more non-transitory computer-readable media 737 with stored instructions, firmware, and/or combinations thereof. While the logic 730 is illustrated as a hardware component attached to the bus 725, it is to be appreciated that in other embodiments, the logic 730 could be implemented in the processor 710, stored in memory 715, or stored in disk 735.

In one embodiment, logic 730 or the computer is a means (e.g., structure: hardware, non-transitory computer-readable medium, firmware) for performing the actions described. In some embodiments, the computing device may be a server operating in a cloud computing system, a server configured in a Software as a Service (SaaS) architecture, a smart phone, laptop, tablet computing device, and so on.

The means may be implemented, for example, as an application-specific integrated circuit (ASIC) programmed to facilitate LLM-based generation and deployment of designs for computing infrastructure. The means may also be implemented as stored computer executable instructions that are presented to computer 705 as data 740 that are temporarily stored in memory 715 and then executed by processor 710.

Logic 730 may also provide means (e.g., hardware, non-transitory computer-readable medium that stores executable instructions, firmware) for performing one or more of the disclosed functions and/or combinations of the functions.

Generally describing an example configuration of the computer 705, the processor 710 may be a variety of various processors including dual microprocessor and other multi-processor architectures. A memory 715 may include volatile memory and/or non-volatile memory. Non-volatile memory may include, for example, read-only memory (ROM), programmable ROM (PROM), and so on. Volatile memory may include, for example, random access memory (RAM), static RAM (SRAM), dynamic RAM (DRAM), and so on.

A storage disk 735 may be operably connected to the computer 705 via, for example, an input/output (I/O) interface (e.g., card, device) 745 and an input/output port 720 that are controlled by at least an input/output (I/O) controller 747. The disk 735 may be, for example, a magnetic disk drive, a solid-state drive, a floppy disk drive, a tape drive, a Zip drive, a flash memory card, a memory stick, and so on. Furthermore, the disk 735 may be a compact disc ROM (CD-ROM) drive, a CD recordable (CD-R) drive, a CD rewritable (CD-RW) drive, a digital video disc ROM (DVD ROM) drive, and so on. The storage/disks thus may include one or more non-transitory computer-readable media. The memory 715 can store a process 750 and/or a data 740, for example. The disk 735 and/or the memory 715 can store an operating system that controls and allocates resources of the computer 705.

The computer 705 may interact with, control, and/or be controlled by input/output (I/O) devices via the input/output (I/O) controller 747, the I/O interfaces 745, and the input/output ports 720. Input/output devices may include, for example, one or more network devices 755, displays 770, printers 772 (such as inkjet, laser, or 3D printers), audio output devices 774 (such as speakers or headphones), text input devices 780 (such as keyboards), cursor control devices 782 for pointing and selection inputs (such as mice, trackballs, touch screens, joysticks, pointing sticks, electronic styluses, electronic pen tablets), audio input devices 784 (such as microphones or external audio players), video input devices 786 (such as video and still cameras, or external video players), image scanners 788, video cards (not shown), disks 735, and so on. The input/output ports 720 may include, for example, serial ports, parallel ports, and USB ports.

The computer 705 can operate in a network environment and thus may be connected to the network devices 755 via the I/O interfaces 745, and/or the I/O ports 720. Through the network devices 755, the computer 705 may interact with a network 760. Through the network 760, the computer 705 may be logically connected to remote computers 765. Networks with which the computer 705 may interact include, but are not limited to, a local area network (LAN), a wide area network (WAN), and other networks.

### Definitions and Other Embodiments

In another embodiment, the described methods and/or their equivalents may be implemented with computer executable instructions. Thus, in one embodiment, a non-transitory computer readable/storage medium is configured with stored computer executable instructions of an algorithm/executable application that when executed by a machine(s) cause the machine(s) (and/or associated components) to perform the method. Example machines include but are not limited to a processor, a computer, a server operating in a cloud computing system, a server configured in a Software as a Service (SaaS) architecture, a smart phone, and so on). In one embodiment, a computing device is implemented with one or more executable algorithms that are configured to perform any of the disclosed methods.

In one or more embodiments, the disclosed methods or their equivalents are performed by either: computer hardware configured to perform the method; or computer instructions embodied in a module stored in a non-transitory computer-readable medium where the instructions are configured as an executable algorithm configured to perform the method when executed by at least a processor of a computing device.

While for purposes of simplicity of explanation, the illustrated methodologies in the figures are shown and described as a series of blocks of an algorithm, it is to be appreciated that the methodologies are not limited by the order of the blocks. Some blocks can occur in different orders and/or concurrently with other blocks from that shown and described. Moreover, less than all the illustrated blocks may be used to implement an example methodology. Blocks may be combined or separated into multiple actions/components. Furthermore, additional and/or alternative methodologies can employ additional actions that are not illustrated in blocks. The methods described herein are limited to statutory subject matter under 35 U.S.C. § 101.

The following includes definitions of selected terms employed herein. The definitions include various examples and/or forms of components that fall within the scope of a term and that may be used for implementation. The examples are not intended to be limiting. Both singular and plural forms of terms may be within the definitions.

References to “one embodiment”, “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in one embodiment” does not necessarily refer to the same embodiment, though it may.

A “data structure”, as used herein, is an organization of data in a computing system that is stored in a memory, a storage device, or other computerized system. A data structure may be any one of, for example, a data field, a data file, a data array, a data record, a database, a data table, a graph, a tree, a linked list, and so on. A data structure may be formed from and contain many other data structures (e.g., a database includes many data records). Other examples of data structures are possible as well, in accordance with other embodiments.

“Computer-readable medium” or “computer storage medium”, as used herein, refers to a non-transitory medium that stores instructions and/or data configured to perform one or more of the disclosed functions when executed. Data may function as instructions in some embodiments. A computer-readable medium may take forms, including, but not limited to, non-volatile media, and volatile media. Non-volatile media may include, for example, optical disks, magnetic disks, and so on. Volatile media may include, for example, semiconductor memories, dynamic memory, and so on. Common forms of a computer-readable medium may include, but are not limited to, a floppy disk, a flexible disk, a hard disk, a magnetic tape, other magnetic medium, an application specific integrated circuit (ASIC), a programmable logic device, a compact disk (CD), other optical medium, a random access memory (RAM), a read only memory (ROM), a memory chip or card, a memory stick, solid state storage device (SSD), flash drive, and other media from which a computer, a processor or other electronic device can function with. Each type of media, if selected for implementation in one embodiment, may include stored instructions of an algorithm configured to perform one or more of the disclosed and/or claimed functions. Computer-readable media described herein are limited to statutory subject matter under 35 U.S.C. § 101.

“Logic”, as used herein, represents a component that is implemented with computer or electrical hardware, a non-transitory medium with stored instructions of an executable application or program module, and/or combinations of these to perform any of the functions or actions as disclosed herein, and/or to cause a function or action from another logic, method, and/or system to be performed as disclosed herein. Equivalent logic may include firmware, a microprocessor programmed with an algorithm, a discrete logic (e.g., ASIC), at least one circuit, an analog circuit, a digital circuit, a programmed logic device, a memory device containing instructions of an algorithm, and so on, any of which may be configured to perform one or more of the disclosed functions. In one embodiment, logic may include one or more gates, combinations of gates, or other circuit components configured to perform one or more of the disclosed functions. Where multiple logics are described, it may be possible to incorporate the multiple logics into one logic. Similarly, where a single logic is described, it may be possible to distribute that single logic between multiple logics. In one embodiment, one or more of these logics are corresponding structure associated with performing the disclosed and/or claimed functions. Choice of which type of logic to implement may be based on desired system conditions or specifications. For example, if greater speed is a consideration, then hardware would be selected to implement functions. If a lower cost is a consideration, then stored instructions/executable application would be selected to implement the functions. Logic is limited to statutory subject matter under 35 U.S.C. § 101.

An “operable connection”, or a connection by which entities are “operably connected”, is one in which signals, physical communications, and/or logical communications may be sent and/or received. An operable connection may include a physical interface, an electrical interface, and/or a data interface. An operable connection may include differing combinations of interfaces and/or connections sufficient to allow operable control. For example, two entities can be operably connected to communicate signals to each other directly or through one or more intermediate entities (e.g., processor, operating system, logic, non-transitory computer-readable medium). Logical and/or physical communication channels can be used to create an operable connection.

“User”, as used herein, includes but is not limited to one or more persons, computers or other devices, or combinations of these.

While the disclosed embodiments have been illustrated and described in considerable detail, it is not the intention to restrict or in any way limit the scope of the appended claims to such detail. It is, of course, not possible to describe every conceivable combination of components or methodologies for purposes of describing the various aspects of the subject matter. Therefore, the disclosure is not limited to the specific details or the illustrative examples shown and described. Thus, this disclosure is intended to embrace alterations, modifications, and variations that fall within the scope of the appended claims, which satisfy the statutory subject matter requirements of 35 U.S.C. § 101.

To the extent that the term “includes” or “including” is employed in the detailed description or the claims, it is intended to be inclusive in a manner similar to the term “comprising” as that term is interpreted when employed as a transitional word in a claim.

To the extent that the term “or” is used in the detailed description or claims (e.g., A or B) it is intended to mean “A or B or both”. When the applicants intend to indicate “only A or B but not both” then the phrase “only A or B but not both” will be used. Thus, use of the term “or” herein is the inclusive, and not the exclusive use.

What is claimed is:

1. One or more non-transitory computer-readable media that include stored thereon computer-executable instructions that, when executed by at least a processor of a computing system, cause the computing system to:
access infrastructure requirements for compute infrastructure that are in human language;
translate the infrastructure requirements into a physical infrastructure topology using one or more large language models;
convert the physical infrastructure topology into an executable deployment specification; and
execute the deployment specification to automatically configure a target computer system to have the compute infrastructure described by the infrastructure requirements.

2. The one or more non-transitory computer-readable media of claim 1, wherein the computer-executable instructions to translate the infrastructure requirements into the physical infrastructure topology further cause the computing system to:
translate the infrastructure requirements into a logical infrastructure topology using a first large language model that is trained to generate logical infrastructure topologies; and
translate the infrastructure requirements and the logical infrastructure topology into the physical infrastructure topology using a second large language model that is trained to generate physical infrastructure topologies.

3. The one or more non-transitory computer-readable media of claim 2, wherein the computer-executable instructions to translate the infrastructure requirements into the physical infrastructure topology further cause the computing system to:
present the logical infrastructure topology as a logical infrastructure topology graph for a first user approval before proceeding to translate the logical infrastructure topology into the physical infrastructure topology; and
present the physical infrastructure topology as a physical infrastructure topology graph for a second user approval before proceeding to convert the physical infrastructure topology into the executable deployment specification.

4. The one or more non-transitory computer-readable media of claim 1, wherein the executable deployment specification is written in YAML code or HCL code.

5. The one or more non-transitory computer-readable media of claim 1, wherein the computer-executable instructions further cause the computing system to:
access a training set of associated training logical infrastructure topologies, training physical infrastructure topologies, and training infrastructure requirements for other computing infrastructure;
train one large language model of the one or more large language models to generate the physical infrastructure topologies using the training physical infrastructure topologies, training logical infrastructure topologies, and training infrastructure requirements in the training set.

6. The one or more non-transitory computer-readable media of claim 1, wherein the computer-executable instructions further cause the computing system to validate the translation using one or more further large language models that are trained to detect errors in infrastructure topologies.

7. The one or more non-transitory computer-readable media of claim 1, wherein the computer-executable instructions to translate the infrastructure requirements into a physical infrastructure topology further cause the computing system to represent the physical infrastructure topology as a collection of tokens in a graph representation language.

8. A computer-implemented method, comprising:
accessing infrastructure requirements for compute infrastructure that are in human language;
translating the infrastructure requirements into a logical infrastructure topology using a first large language model that is trained to generate logical infrastructure topologies;
translating the infrastructure requirements and the logical infrastructure topology into a physical infrastructure topology using a second large language model that is trained to generate physical infrastructure topologies;
converting the physical infrastructure topology into an executable deployment specification; and
executing the deployment specification to automatically configure a target computer system to have the compute infrastructure described by the infrastructure requirements.

9. The computer-implemented method of claim 8, further comprising:
presenting the logical infrastructure topology as a logical infrastructure topology graph for a first user approval before proceeding to translate the logical infrastructure topology into the physical infrastructure topology; and
presenting the physical infrastructure topology as a physical infrastructure topology graph for a second user approval before proceeding to convert the physical infrastructure topology into the executable deployment specification.

10. The computer-implemented method of claim 8, wherein the executable deployment specification is written in YAML code.

11. The computer-implemented method of claim 8, wherein the executable deployment specification is written in HCL code.

12. The computer-implemented method of claim 8, further comprising:
automatically validating the logical infrastructure topology with a third large language model that is trained to detect whether there exist errors in the logical infrastructure topology; and
automatically validating the physical infrastructure topology with a fourth large language model that is trained to detect whether there exist errors in the physical infrastructure topology.

13. The computer-implemented method of claim 8, further comprising:
in response to detection of an error in the logical infrastructure topology, automatically update first training data for the first large language model with corrections to the error in the logical infrastructure topology, and re-train the first large language model with the updated first training data; and
in response to detection of an error in the physical infrastructure topology, automatically update second training data for the second large language model with corrections to the error in the physical infrastructure topology, and re-train the second large language model with the updated second training data.

14. The computer-implemented method of claim 8, wherein the logical infrastructure topology and the physical infrastructure topology are generated as collections of tokens in a graph representation language.

15. A computing system, comprising:
a processor;
a memory;
one or more non-transitory computer-readable media that include stored thereon computer-executable instructions that, when executed by at least the processor, cause the computing system to:
access infrastructure requirements for compute infrastructure that are in human language;
translate the infrastructure requirements into a physical infrastructure topology using one or more large language models;
convert the physical infrastructure topology into an executable deployment specification; and
execute the deployment specification to automatically configure infrastructure of the computing system as described by the infrastructure requirements.

16. The computing system of claim 15, wherein translation of the infrastructure requirements into the physical infrastructure topology further comprises translating the infrastructure requirements into an intermediate logical infrastructure topology prior to producing the physical infrastructure topology.

17. The computing system of claim 16, wherein the computer-executable instructions to translate the infrastructure requirements into the physical infrastructure topology further cause the computing system to:
present the logical infrastructure topology as a logical infrastructure topology graph for a first user approval before proceeding to translate the logical infrastructure topology into the physical infrastructure topology; and
present the physical infrastructure topology as a physical infrastructure topology graph for a second user approval before proceeding to convert the physical infrastructure topology into the executable deployment specification.

18. The computing system of claim 16,
wherein the computer-executable instructions to translate the infrastructure requirements into a logical infrastructure topology further cause the computing system to represent the logical infrastructure topology as a first collection of tokens in a graph representation language; and
wherein the computer-executable instructions to translate the infrastructure requirements and the logical infrastructure topology into a physical infrastructure topology further cause the computing system to represent the physical infrastructure topology as a second collection of tokens in the graph representation language.

19. The computing system of claim 15, wherein the executable deployment specification is written in YAML code or HCL code.

20. The computing system of claim 15, wherein the computer-executable instructions further cause the computing system to:
access a training set of associated training logical infrastructure topologies, training physical infrastructure topologies, and training infrastructure requirements for other computing infrastructure;
train the one or more large language models to generate the physical infrastructure topologies using the training g infrastructure requirements and at least one of the training physical infrastructure topologies, training logical infrastructure topologies in the training set.
